(19) United States
(12) Patent Application Publication
(10) Pub. No.: US 2012/0253716 A1
(43) Pub. Date: Oct. 4, 2012

(54) BATTERY VOLTAGE DETECTOR

(75) Inventors: Shingo TSUCHIYA, Utsunomiya-shi (JP); Seiji KAMATA, Utsunomiya-shi (JP); Kouji SUZUKI, Utsunomiya-shi (JP)

(73) Assignee: KEIHIN CORPORATION, Tokyo (JP)

(21) Appl. No.: 13/429,935

(22) Filed: Mar. 26, 2012

(30) Foreign Application Priority Data
Mar. 30, 2011 (JP) 2011-075303

(51) Int. Cl. G01R 31/36

(52) U.S. Cl. 702/63

(57) ABSTRACT

A battery voltage detector includes a voltage detection circuit and a voltage processor. The voltage detection circuit includes a capacitor, a pair of output terminals and an output switch. A power source voltage is supplied from a power source to a higher voltage output terminal of the pair of output terminals in the voltage detection circuit. While the output switch is turned off, the voltage processor takes in a voltage between the output terminals as a voltage for determining a defect and determines whether or not a false detection of the cell voltage has occurred based on the voltage for determining the defect.

Priority is claimed on Japanese Patent Application No. 2011-075303, filed Mar. 30, 2011, the content of which is incorporated herein by reference.

### BACKGROUND OF THE INVENTION

1. Field of the Invention

The present invention generally relates to a battery voltage detector.

2. Description of Related Art

As is generally known, vehicles such as electric vehicles and hybrid vehicles are equipped with a motor which is a power source and a battery of high voltage and large capacitance, which supplies electric power to the motor. The battery is configured by serially connecting a plurality of battery cells such as lithium-ion batteries or nickel-hydrogen batteries. Cell balance control in which cell voltages of each battery cell are monitored and the cell voltages are homogenized has been performed in order to maintain the performance of the battery.

In detection of the cell voltage, a flying capacitor-type voltage detection circuit, which does not require a dedicated insulating power source or an insulator, is mainly used. In the flying capacitor-type voltage detection circuit, because of aging, the cell voltage of the object to be measured is detected as a lower voltage than an actual value when leakage current of a flying capacitor and a sampling switch is increased. As a result, accuracy of the cell balance control may be lowered because the correct cell voltage cannot be obtained.

Japanese Unexamined Patent Application, First Publication, No. 2002-291167 discloses the following method that overcomes the above-described defect of the flying capacitor-type voltage detection circuit. The cell voltage of the battery cell, which is the measuring object, is detected by the flying capacitor-type voltage detection circuit at a different timing in chronological order. A voltage just after starting charging the flying capacitor, which can be regarded as the actual value of the cell voltage, is estimated based on the voltage attenuation property of the cell voltage, which is obtained from the detected result.

### SUMMARY OF THE INVENTION

Japanese Unexamined Patent Application, First Publication, No. 2002-291167 discloses a technology in which an accurate cell voltage is detected by a flying capacitor-type voltage detection circuit. More specifically, the cell voltage, which can be regarded as the actual value, is estimated by arithmetic processing. However, the technology disclosed by Japanese Unexamined Patent Application, First Publication, No. 2002-291167 is not directed to detect an occurrence of a false detection of the cell voltage caused by aging. It is important for properly controlling the battery to detect the cell voltage correctly. However, it is also important to detect the occurrence of a false detection of the cell voltage, that is, the generation of a defect of the circuit.

One embodiment of the present invention has been made in view of the circumstances described above, and has an object to provide a battery voltage detector that can detect the occurrence of a false detection of a cell voltage due to aging of a voltage detection circuit.

In order to accomplish the above object, according to a first embodiment of the present invention, a battery voltage detector may include, but is not limited to, a voltage detection circuit and a voltage processor. The voltage detection circuit may include, but is not limited to, a capacitor charged by a first battery cell, a pair of output terminals, and an output switch. The output switch is turned off and insulates the capacitor and the pair of the output terminals in the period of charging the capacitor. The output switch is turned on and couples the capacitor and the pair of output terminals after charging the capacitor. The voltage processor takes in a voltage between the pair of output terminals as a cell voltage of the first battery cell while the output switch is turned on. A power source voltage is supplied from a power source to a higher voltage output terminal of the pair of output terminals in the voltage detection circuit. While the output switch is turned off, the voltage processor takes in a voltage between the output terminals as a voltage for determining a defect and determines whether or not a false detection of the cell voltage has been occurred based on the voltage for determining the defect.

In some cases, the battery voltage detector may include, but is not limited to, the voltage processor which determines that the false detection of the cell voltage has occurred when the voltage for determining the defect is lower than a predetermined threshold value.

In some cases, in the battery voltage detector, the power source may be a reference power source.

In some cases, the battery voltage detector may include, but is not limited to, the voltage detection circuit provided with each of second battery cells which are coupled to each other in series and include the first battery cell. Each of the voltage detection circuits may include, but is not limited to, a pair of input terminals coupled and an input switch. The pair of input terminals is coupled to both terminals of the second battery. The input switch is turned on and couples the capacitor to the pair of the input terminals in the period of charging the capacitor. The input switch is turned off and insulates the capacitor and the pair of the input terminals after charging the capacitor.

In some cases, the battery voltage detector may include, but is not limited to, the voltage processor which determines whether or not the false detection of the cell voltage has occurred based on the voltage for determining a defect in synchronization with timing of charging the capacitor.

When the higher voltage output terminal of the pair of the output terminals in the voltage detection circuit is connected to a power source line, the voltage between the output terminals of the voltage detection circuit, which is obtained while the output switch is turned off (the state where the capacitor is insulated from the output terminals and charged by the battery cell), is substantially the same as a potential of the power source line in the case where a leakage current occurred in a later stage of the output switch is sufficiently small (a leakage resistance is sufficiently large). However, when the leakage current is increased (the leakage resistance is decreased), the voltage between the output terminals of the voltage detection circuit is decreased.

According to one embodiment of the present invention, while the output switch is turned off, the voltage processor takes in the voltage between the output terminals of the voltage detection circuit as a voltage for determining a defect and determines whether or not the false detection of the cell voltage has occurred based on the voltage for determining the defect. By virtue of this, the occurrence of a false detection of the cell voltage (generation of a defect of the circuit between the voltage detection circuit and the voltage processor) caused by aging (increase of the leakage current) of the cell voltage detection circuits can be detected by a simple configuration. As a result, this contributes to the proper control of the battery.

### BRIEF DESCRIPTION OF THE DRAWINGS

FIG. 1 is a diagram illustrating a schematic configuration of a battery voltage detector 1 in accordance with one embodiment of the present invention;

FIG. 2 is a schematic circuit diagram of a cell voltage detection circuit D1 in accordance with one embodiment of the present invention;

FIG. 3 is a timing chart showing an operation of a battery voltage detector 1 in accordance with one embodiment of the present invention; and

FIG. 4 is a graph showing (a) a V-RL characteristic of a detected voltage value V between output terminals of the cell voltage detection circuit D1 in which a microcomputer M takes in a period of time between t3 and t4 and leakage resistance RL, (b) a V-RL characteristic of a detected voltage value V between output terminals of the cell voltage detection circuit D1 in which the microcomputer M takes in a charging period between t1 and t2 and leakage resistance RL, and (c) a state of a defect flag, in accordance with one embodiment of the present invention.

### DETAILED DESCRIPTION OF THE INVENTION

Hereinafter, one embodiment of the present invention will be described with reference to the drawings.

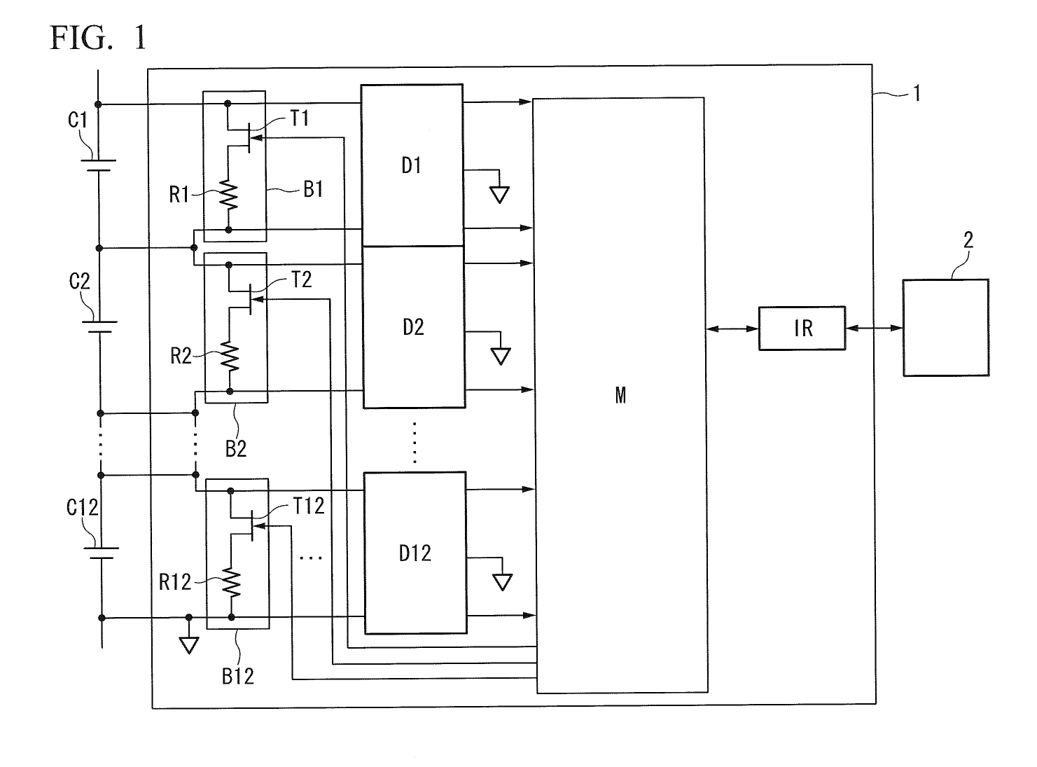

FIG. 1 is a diagram illustrating a schematic configuration of a battery voltage detector 1 in accordance with one embodiment of the present invention. As shown in FIG. 1, a battery voltage detector 1 is an ECU (Electronic Control Unit) which has a function of detecting cell voltages of twelve battery cells C1 to C12 and a function of performing a cell balance control (homogenization of the cell voltages) of each of the battery cells C1 to C12. The battery cells C1 to C12 form a battery. The battery voltage detector 1 includes twelve bypass circuits B1 to B12, twelve cell voltage detection circuits D1 to D12, a microcomputer M (voltage processor), and an insulating element IR.

Each of the bypass circuits B1 to B12 is constructed of a series circuit of a bypass resistance and a switching element such as a transistor. The bypass circuits B1 to B12 are connected to the battery cells C1 to C12 in parallel, respectively. R1 to R12 denote bypass resistances included in the bypass circuits B1 to B12, respectively. In FIGS. 1, T1 to T12 denote switching elements included in the bypass circuits B1 to B12, respectively.

The cell voltage detection circuits D1 to D12 are connected to the battery cell C1 to C12 in series, respectively, as a so-called single flying capacitor-type voltage detection circuit.

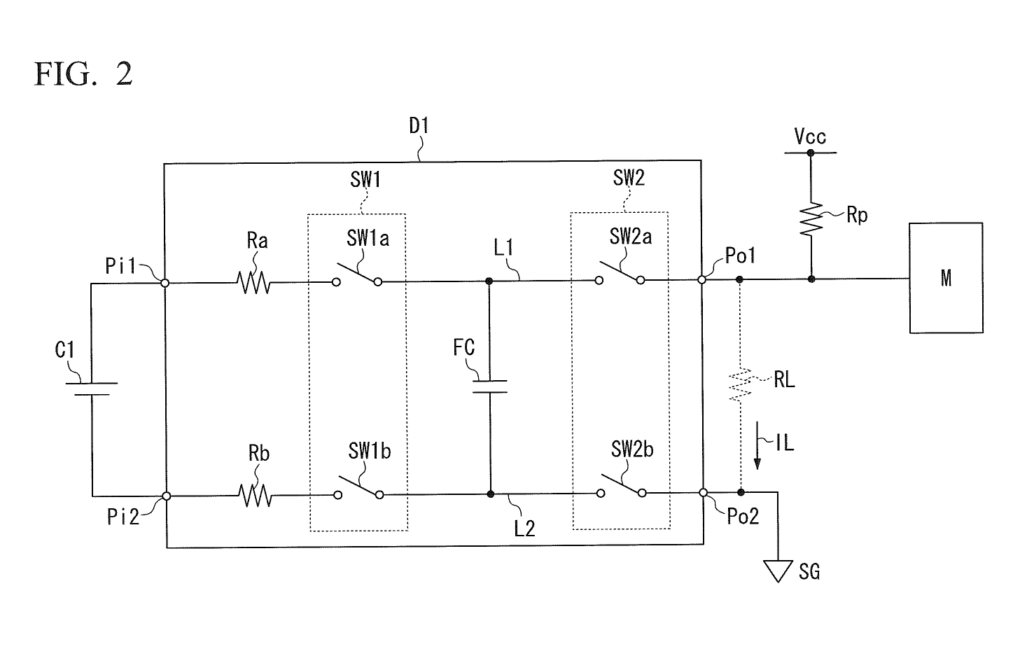

FIG. 2 illustrates a schematic circuit diagram of the cell voltage detection circuit D1 which detects a cell voltage of the battery cell C1.

Since the other cell voltage detection circuits D2 to D12 have the same configuration as the cell voltage detection circuit D1, the cell voltage detection circuit D1 is used as a representative example and the circuit configuration thereof will be described in detail.

As shown in FIG. 2, reference numeral Pi1 denotes a first input terminal connected to a positive terminal of the battery cell C1. Reference numeral Pi2 denotes a second input terminal connected to a negative terminal of the battery cell C1. Reference numeral Po1 denotes a first output terminal connected to an input port of the microcomputer M, which is a port connected to the A/D converter. Reference numeral Po2 denotes a second output terminal connected to a common line which is a grounded line SG, for example, in the battery voltage detector 1.

The first input terminal Pi1 and the second input terminal Pi2 described above correspond to a pair of input terminals according to the present embodiment. The first output terminal Po1 and the second output terminal Po2 described above correspond to a pair of output terminals according to the present embodiment.

Reference numeral FC denotes a flying capacitor (capacitor) connected between the high voltage line L1 and the low voltage line L2. The high voltage line L1 connects the first input terminal Pi1 and the first output terminal Po1. The low voltage line L2 connects the second input terminal Pi2 and the second output terminal Po2. Reference numeral SW1 denotes an input switch inserted in a former stage of the flying capacitor FC in the high voltage line L1 and the low voltage line L2.

Specifically, the input switch SW1 includes a first input switch SW1a and a second input switch SW1b. The first input switch SW1a is inserted in a former stage of the flying capacitor FC in the high voltage line L1. The second input switch SW1b is inserted in a former stage of the flying capacitor FC of the low voltage line L2. An insert resistance Ra is inserted in a former stage of the first input switch SW1a in the high voltage line L1. An insert resistance Rb is inserted in a former stage of the second input switch SW1b in the low voltage line L2.

The input switch SW1 is turned on during a period of charging the flying capacitor FC and connects the flying capacitor FC between the input terminals. Namely, the input switch SW1 connects the flying capacitor FC to the battery cell C1. Also, the input switch SW1 is turned off after charging the flying capacitor FC and insulates the flying capacitor FC from the input terminals. Namely, the input switch SW1 insulates the flying capacitor FC from the battery cell C1.

Reference numeral SW2 denotes an output switch inserted in a later stage of the flying capacitor FC in the high voltage line L1 and the low voltage line L2. Specifically, the output switch SW2 includes a first output switch SW2a and a second output switch SW2b. The first output switch SW2a is inserted in a later stage of the flying capacitor FC in the high voltage line L1. The second output switch SW2b is inserted in a later stage of the flying capacitor FC in the low voltage line L2.

The output switch SW2 is turned off during the period of charging the flying capacitor FC and insulates the flying capacitor FC from the output terminals. Namely, the output switch SW2 insulates the flying capacitor FC from the microcomputer M, which is disposed in a later stage of the flying capacitor FC. The output switch SW2 is turned on after charging the flying capacitor FC and connects the flying capacitor FC between the output terminals. Namely, the output switch SW2 connects the flying capacitor FC to the microcomputer M.

The first output terminal Po1, which is a higher voltage output terminal of the pair of output terminals (the first output terminal Po1 and the second output terminal Po2) with which the cell voltage detection circuit D1 is provided, is supplied with a power source voltage through a pull-up resistor Rp from a power source in the battery voltage detector 1 which is, for example, a power source of Vcc=5V. Although not shown in the drawings, the power source is a reference power source which generates a stable reference voltage (Vcc). The reference voltage (Vcc) is a reference of circuit operation.

In FIG. 2, a leakage resistor RL shown in a broken line does not exist as an actual circuit element. The leakage resistor RL is illustrated in order to equivalently describe how leakage current IL, which is generated because of aging of the cell voltage detection circuit D1, flows. When aging of the cell voltage detection circuit D1 progresses, resistance of the leakage resistor RL decreases and the leakage current IL increases.

The above is an explanation regarding the specific circuit configuration of the cell voltage detection circuit D1 (which is similar to the cell voltage detection circuit D2 through D12). The following explanation refers back to FIG. 1. The microcomputer M is a microcontroller integrally embedded with memories such as a ROM and a RAM, a CPU (Central Processing Unit), an A/D converter, an input/output interface, and the like.

The microcomputer M takes in voltages between the output terminals of the cell voltage detection circuits D1 through D12, which are voltages between the first output terminal Po1 and the second output terminal Po2, as cell voltages of the battery cells C1 to C12 while each of the output switches SW2 of the cell voltage detection circuits D1 to D12 is turned on. The microcomputer M memorizes data showing a correspondence between identification numbers of the battery cells C1 to C12 and the cell voltages as a voltage detection result in an internal memory, for example, the RAM.

The microcomputer M is coupled to a battery ECU 2 which is an upper controller via the insulating element IR so as to allow communication with each other. The microcomputer M has a function of transmitting the cell voltage detection result, which is memorized in the internal memory as described above, to the battery ECU 2. The battery ECU 2 monitors a state of the battery cell C1 to C12, which is a balanced state of the cell voltage, based on the cell voltage detection result which is received from the microcomputer M. When the battery ECU 2 finds a battery cell whose cell voltage is higher compared with that of other battery cells, the battery ECU 2 identifies the battery cell as a cell necessitating discharge and transmits the identification result to the microcomputer M.

The microcomputer M also has a function of duty control of the switching element of the bypass circuit connected to the cell necessitating discharge, that is, a cell balance control. In the cell balance control, when the microcomputer M receives the identification result of the cell necessitating discharge from the battery ECU 2, predetermined discharging current flows in the bypass circuit connected to the cell necessitating discharge.

Although a specific explanation will be described later, the microcomputer M according to the present embodiment has a function of taking in the voltage between the output terminals of the cell voltage detection circuits D1 through D12 as a voltage for determining a defect while each of the output switches SW2 of the cell voltage detection circuits D1 through D12 is turned off and determining whether or not a false detection of the cell voltage has occurred based on the voltage for determining the defect (whether a defect has been occurred in the cell voltage detection circuit).

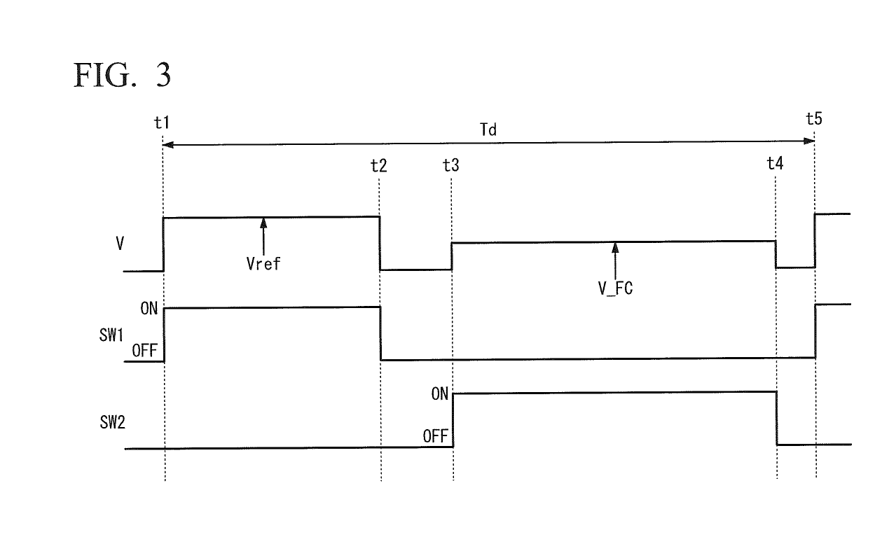

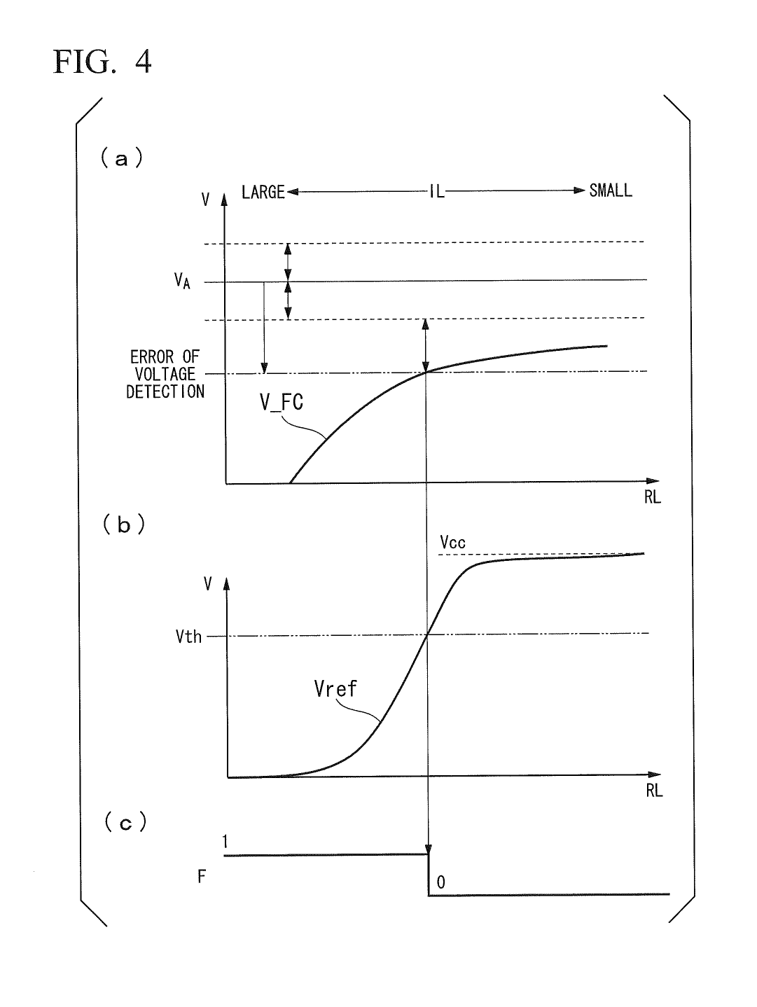

The above is an explanation regarding the configuration of the battery voltage detector 1 according to the present embodiment. An operation of the battery voltage detector 1 having the configuration described above will be described in detail with reference to FIGS. 3 and 4. In particular, the operation when determining whether or not a false detection of the cell voltage has occurred (whether or not a circuit defect has been generated between the cell voltage detection circuit and the microcomputer), which is one feature of the present embodiment, will be described.

The cell voltage detection circuit D1 which detects the cell voltage of the battery cell C1 is used as a representative example and the operation when determining whether or not a false detection of the cell voltage has occurred will be described. However, the cell voltage detection circuits D2 to D12 operate in the same manner as the cell voltage detection circuit D1.

FIG. 3 is a timing chart showing a chronological correspondence between a voltage V between output terminals of the cell voltage detection circuit D1 in which the microcomputer M takes an on/off state of the input switch SW1 of the cell voltage detection circuit D1 (the first input switch SW1a and the second input switch SW1b), and an on/off state of the output switch SW2 (the first output switch SW2a and the second output switch SW2b) in one cycle of the voltage detection cycle Td.

As shown in FIG. 3, if a start timing, which is a start timing for charging the flying capacitor FC, of the voltage detection cycle Td comes at t1, the input switch SW1 (SW1a and SW1b) of the cell voltage detection circuit D1 is turned on while the output switch SW2 (SW2a and SW2b) is turned off. By doing this, the flying capacitor FC starts to be charged by the battery cell C1.

The input switch SW1 is turned off at t2 after a predetermined time has passed from t1. Namely, the input switch SW1 is turned off after the flying capacitor FC has been fully charged. In the charging period between t1 and t2 (the period in which the output switch SW2 is turned off), since the flying capacitor FC and the output terminals (the first output terminal Po1 and the second output terminal Po2) are electrically insulated from each other, the voltage V between output terminals of the cell voltage detection circuit D1 is shown by the following formula (1). In the formula (1), “RL” denotes an electrical resistivity of the leakage resistance RL and “Rp” denotes an electrical resistivity of the pull-up resistor Rp.

V=Vcc×RL/(Rp+RL) (1)

The microcomputer M takes in the voltage V between the output terminals of the cell voltage detection circuit D1 as a voltage Vref for determining the defect in the period of charging the flying capacitor FC between t1 and t2 (the period where the output switch SW2 is turned off). The microcomputer M converts, by the A/D converter, the voltage Vref for determining the defect to digital data which is processable by the CPU and memorizes the digital data in an internal memory, for example, the RAM.

After charging the flying capacitor FC, the output switch SW2 is turned on in a period between t3 and t4 while the input switch SW1 is turned off. In the period between t3 and t4, that is, the period in which the output switch SW2 is turned on, since the flying capacitor FC and the output terminals (the first output terminal Po1 and the second output terminal Po2) are electrically connected to each other, the voltage V between output terminals of the cell voltage detection circuit D1 is substantially the same as a voltage between terminals of the flying capacitor FC.

The microcomputer M takes in the voltage V between output terminals of the cell voltage detection circuit D1 as a cell voltage V_FC of the battery cell C1. The microcomputer M converts, by the A/D converter, the cell voltage V_FC to digital data which is processable by the CPU and memorizes the digital data in the internal memory, for example, the RAM.

As described above, when obtaining the voltage Vref for determining the defect and the cell voltage V_FC, the microcomputer M reads out the voltage Vref for determining the defect from the internal memory and determines whether or not the voltage Vref for determining the defect is lower than a predetermined threshold value Vth.

(a) of FIG. 4 is a graph showing a V-RL characteristic of the voltage V between output terminals of the cell voltage detection circuit D1 (that is, the cell voltage V_FC) in which the microcomputer M takes in the period between t3 and t4 (the period in which the output switch SW2 is turned on) and the leakage resistance RL (refer to FIG. 2). (b) of FIG. 4 is a graph showing a V-RL characteristic of the voltage V between output terminals of the cell voltage detection circuit D1 (that is, the voltage Vref for determining the defect) in which the microcomputer M takes in the charging period between t1 and t2 (the period in which the output switch SW2 is turned off) and the leakage resistance RL.

As shown in (a) of FIG. 4, when aging of the cell voltage detection circuit D1 progresses and an electrical resistivity of the leakage resistance RL is decreased, namely, the leakage current IL is increased, an error of the cell voltage V_FC with respect to an actual cell voltage V_{A} of the battery cell C1 becomes larger. Also, as shown in (b) of FIG. 4, in the case where aging of the cell voltage detection circuit D1 does not progress and an electrical resistivity of the leakage resistance RL is large enough to ignore an electrical resistivity of the pull-up resistor Rp, a voltage Vref for determining a defect is substantially the same as Vcc (refer to the above-described formula (1)).

On the other hand, when aging of the cell voltage detection circuit D1 progresses and an electrical resistivity of the leakage resistance RL is decreased, namely, the leakage current IL is increased, an electrical resistivity of the pull-up resistor Rp cannot be ignored with respect to the electrical resistivity of the leakage resistance RL. Thereby, a voltage Vref for determining a defect is gradually decreased. Therefore, when a voltage Vref for determining a defect becomes lower than a threshold value Vth, which is the allowable lowest limit, it is determined that a false detection of the cell voltage has occurred (a circuit defect has been generated between the cell voltage detection circuit D1 and the microcomputer M).

The microcomputer M determines whether or not a voltage Vref for determining a defect is lower than the threshold value Vth. When the voltage Vref for determining the defect is lower than the threshold value Vth, the microcomputer M determines that a false detection of the cell voltage has occurred (a circuit defect has been generated between the cell voltage detection circuit D1 and the microcomputer M) and sets a defect flag as “1”. On the other hand, when the voltage Vref for determining the defect is equal to or higher than the threshold value Vth, the microcomputer M determines that the cell voltage has been correctly detected (a circuit has been normal between the cell voltage detection circuit D1 and the microcomputer M) and sets a defect flag as “0” (refer to (c) of FIG. 4).

When setting the defect flag as “0”, the microcomputer M sends the cell voltage V_FC memorized in the internal memory as a detection result of the cell voltage of the battery cell C1 to the battery ECU2. When setting the defect flag as “1”, the microcomputer M sends the defect flag instead of the detection result of the cell voltage of the battery cell C1 to the battery ECU2 and notifies the battery ECU2 that a false detection of the cell voltage has occurred (a circuit defect has been generated between the cell voltage detection circuit D1 and the microcomputer M).

The battery voltage detector 1 continuously monitors whether or not a false detection of the cell voltage of each of battery cells C1 to C12 has occurred (a defect of the cell voltage detection circuits D1 to D12 has been generated) by repeatedly performing the above-described sequence of operations in the voltage detection cycle Td. In the case where a false detection of the cell voltage has occurred (a circuit defect has been generated between the cell voltage detection circuit D1 and the microcomputer M), the battery voltage detector 1 timely notifies the battery ECU2. Here, the on/off states of the input switch SW1 and the output switch SW2 may be controlled by the microcomputer M. Also, another controller may be provided to control the on/off states.

As described above, according to the present embodiment, while the output switch SW2 is turned off, the microcomputer M takes in the voltages V between the output terminals of the cell voltage detection circuits D1 to D12 as a voltage Vref for determining a defect and determines whether or not a false detection of the cell voltage has occurred based on the voltage Vref for determining the defect. By virtue of this, an occurrence of a false detection of the cell voltage (a circuit defect generated between the cell voltage detection circuit D1 and the microcomputer M) caused by aging (for example, increase of the leakage current occurring in the later stage of the output switch SW2) of the flying capacitor-type cell voltage detection circuits D1 to D12 can be detected by a simple configuration. As a result, this contributes to the proper control of the battery.

The present invention is not limited to the above-described embodiment, and modified examples can be given as follows.

For example, according to the above-described embodiment, the battery voltage detector 1 performing cell voltage detection of twelve battery cells C1 to C12 is exemplarily shown. However, the number of battery cells to be detected is not limited to twelve. Further, an example in which twelve cell voltage detection circuits D1 to D12 are provided in correspondence with the battery cells C1 to C12 is shown in the above-described embodiment. However, one cell voltage detection circuit may be provided and cell voltages of each of the battery cells C1 to C12 may be sequentially detected while both terminals of the battery cells C1 to C12 and both input terminals (the first input terminal Pi1 and the second input terminal Pi2) of the cell voltage detection circuit are sequentially connected by a multiplexer. When the multiplexer is used, the input switch SW1 is unnecessary. Additionally, according to the above-described embodiment, the power source voltage is supplied from the power source (for example, the power source of Vcc=5V) in the battery voltage detector 1 through the pull-up resistor Rp. However, a switch may be used instead of the pull-up resistor Rp.

While preferred embodiments of the invention have been described and illustrated above, it should be understood that these are exemplary of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

What is claimed is:

1. A battery voltage detector comprising:
a voltage detection circuit comprising a capacitor charged by a first battery cell; a pair of output terminals; and an output switch, wherein the output switch is turned off and insulates the capacitor and the pair of the output terminals in the period of charging the capacitor and wherein the output switch is turned on and couples the capacitor and the pair of output terminals after charging the capacitor; and
a voltage processor taking in a voltage between the pair of output terminals as a cell voltage of the first battery cell while the output switch is turned on,
wherein a power source voltage is supplied from a power source to a higher voltage output terminal of the pair of output terminals in the voltage detection circuit,
wherein while the output switch is turned off, the voltage processor takes in a voltage between the output terminals as a voltage for determining a defect and determines whether or not a false detection of the cell voltage has occurred based on the voltage for determining the defect.

2. The battery voltage detector according to claim 1, wherein the voltage processor determines that the false detection of the cell voltage has occurred when the voltage for determining the defect is lower than a predetermined threshold value.

3. The battery voltage detector according to claim 2, wherein the power source is a reference power source.

4. The battery voltage detector according to claim 2, wherein the voltage detection circuit is provided with each of second battery cells which are coupled to each other in series and include the first battery cell,
wherein each of the voltage detection circuits comprises:
a pair of input terminals coupled to both terminals of the second battery; and
an input switch, wherein the input switch is turned on and couples the capacitor to the pair of the input terminals in the period of charging the capacitor and wherein the input switch is turned off and insulates the capacitor and the pair of the input terminals after charging the capacitor.

5. The battery voltage detector according to claim 1, wherein the power source is a reference power source.

6. The battery voltage detector according to claim 5, wherein the voltage detection circuit is provided with each of second battery cells which are coupled to each other in series and include the first battery cell,
wherein each of the voltage detection circuits comprises:
a pair of input terminals coupled to both terminals of the second battery; and
an input switch, wherein the input switch is turned on and couples the capacitor to the pair of the input terminals in the period of charging the capacitor and wherein the input switch is turned off and insulates the capacitor and the pair of the input terminals after charging the capacitor.

7. The battery voltage detector according to claim 1, wherein the voltage detection circuit is provided with each of second battery cells which are coupled to each other in series and include the first battery cell,
wherein each of the voltage detection circuits comprises:
a pair of input terminals coupled to both terminals of the second battery; and
an input switch, wherein the input switch is turned on and couples the capacitor to the pair of the input terminals in the period of charging the capacitor and wherein the input switch is turned off and insulates the capacitor and the pair of the input terminals after charging the capacitor.

8. The battery voltage detector according to claim 1, wherein the voltage processor determines whether or not the false detection of the cell voltage has occurred based on the voltage for determining a defect in synchronization with timing of charging the capacitor.
